(19) United States
(12) Patent Application Publication
(10) Pub. No.: US 2023/0152658 A1
(43) Pub. Date: May 18, 2023

(54) OPTICAL PATH CONTROL MEMBER AND DISPLAY DEVICE COMPRISING SAME

(71) Applicant: LG INNOTEK CO., LTD., Seoul (KR)

(72) Inventors: Hyeon Ji HONG, Seoul (KR); Mun Yeong SON, Seoul (KR); Byung Sook KIM, Seoul (KR)

(73) Assignee: LG INNOTEK CO., LTD., Seoul (KR)

(21) Appl. No.: 17/923,103

(22) PCT Filed: Apr. 28, 2021
(86) PCT No.: PCT/KR2021/005399

§ 371 Date: Nov. 3, 2022

(30) Foreign Application Priority Data
May 7, 2020 (KR) 10-2020-0054313
May 12, 2020 (KR) 10-2020-0056471

(51) Int. Cl. G02F 1/1685; G02F 1/167; G02F 1/1679; C08K 13/02

(52) U.S. Cl. CPC G02F 1/1685; G02F 1/167; G02F 1/1679; C08K 13/02; G02F 2202/28; G02F 1/13394

(57) ABSTRACT

An optical path control member according to an embodiment comprises: a first substrate; a first electrode disposed on the first substrate; a light conversion part disposed on the first electrode; a second substrate disposed on the first substrate; a second electrode disposed under the second substrate; and an adhesive layer disposed between the light conversion part and the second electrode, wherein the light conversion part comprises alternately disposed partition wall portions and accommodation portions, light transmittance of the accommodation portions changes according to voltage application, the upper surfaces of the partition wall portions are in contact with the adhesive layer, the light conversion part is formed of a photocurable resin, the photocurable resin comprises an oligomer, a monomer, a photopolymerization initiator, and an additive, and the additive comprises an antistatic agent in an amount of 1.5 wt % to 3.0 wt %.

### TECHNICAL FIELD

An embodiment relates to an optical path control member, and to a display device including the same.

### BACKGROUND ART

A light blocking film blocks transmitting of light from a light source, and is attached to a front surface of a display panel which is a display device used for a mobile phone, a notebook, a tablet PC, a vehicle navigation device, a vehicle touch, etc., so that the light blocking film adjusts a viewing angle of light according to an incident angle of light to express a clear image quality at a viewing angle needed by a user when the display transmits a screen.

In addition, the light blocking film may be used for the window of a vehicle, building or the like to shield outside light partially to prevent glare, or to prevent the inside from being visible from the outside.

That is, the light blocking film may be an optical path control member that controls the movement path of light to block light in a specific direction and transmit light in a specific direction. Accordingly, it is possible to control the viewing angle of the user by controlling a transmission angle of the light by the light blocking film.

Meanwhile, such a light blocking film may be divided into a light blocking film that can always control the viewing angle regardless of the surrounding environment or the user's environment and a switchable light blocking film that allow the user to turn on/off the viewing angle control according to the surrounding environment or the user's environment.

Such a switchable light blocking film may be implemented by switching a pattern part to a light transmitting part and a light blocking part by filling the inside of the pattern part with particles that may move when a voltage is applied and a dispersion liquid for dispersing the particles and by dispersing and aggregating the particles.

In order to prevent overflow of a filler, a light conversion part having a partition wall portion may be manufactured using a photocurable resin. In this case, the photocurable resin may include an additive for improving releasability or electrical characteristics. Such additives may move on a surface of the resin, and thus there is a problem that optical characteristics of the resin may deteriorate over time and adhesion between the resin and an adhesive layer may be deteriorated.

Therefore, an optical path control member having a new structure capable of solving the above problems is required.

### DISCLOSURE

### Technical Problem

An embodiment relates to an optical path control member having improved reliability by improving adhesive properties. In addition, the embodiment may provide an optical path control member with improved optical characteristics.

### Technical Solution

An optical path control member according to an embodiment includes: a first substrate; a first electrode disposed on the first substrate; a light conversion part disposed on the first electrode; a second substrate disposed on the first substrate; a second electrode disposed under the second substrate; and an adhesive layer disposed between the light conversion part and the second electrode, wherein the light conversion part includes a partition wall portion and an accommodation portion alternately disposed, the accommodation portion has a light transmittance that changes according to application of a voltage, an upper surface of the partition wall portion is in contact with the adhesive layer, the light conversion part is formed of a photocurable resin, the photocurable resin includes an oligomer, a monomer, a photopolymerization initiator, and an additive, and the additive may include an antistatic agent in an amount of 2.0 wt % to 3.0 wt %.

### Advantageous Effects

An optical path control member according to an embodiment can improve adhesive properties of an adhesive layer bonding a first substrate and a second substrate.

The embodiment may improve adhesion between a partition wall portion and the adhesive layer by changing a composition of a photocurable resin used in order to accommodate a light conversion material and prevent overflow of the light conversion material. In detail, the embodiment can reduce a content of an additive included in order to improve releasability or electrical characteristics of the photocurable resin. Accordingly, the embodiment can prevent film removal or delamination between the partition wall portion and the adhesive layer according to movement of the additive included in the resin.

In addition, the embodiment can prevent deterioration of optical characteristics due to movement of additives in the photocurable resin to a surface of the photocurable resin over time. That is, the embodiment can prevent haze change over time by optimizing a material and content of the additive used to form the partition wall portion.

Accordingly, the optical characteristics and durability of the optical path control member and a display device including the same can be improved.

### DESCRIPTION OF DRAWINGS

FIGS. 1 and 2 are perspective views of an optical path control member according to an embodiment.

FIGS. 3 and 4 are a perspective view of a first substrate and a first electrode and a perspective view of a second substrate and a second electrode of the optical path control member according to the embodiment.

FIG. 5 is a cross-sectional view taken along line A-A′ in FIG. 1.

FIGS. 6 and 9 are cross-sectional views taken along line A-A′ in FIG. 1 for describing shapes of various accommodation portions in the optical path control member according to the embodiment.

FIG. 10 is a view showing an example of a principle that an additive adheres to a surface of a partition wall portion in a dispersion liquid.

FIG. 11 is a schematic diagram of dispersion of carbon black and formation of micelles.

FIG. 12 a is a view showing parts of a head and tail according to a type of surfactant, and FIG. 12 b is a view showing an example of a surfactant.

FIG. 13 is a view showing an example of a micellar form of a nonionic surfactant and a micellar form of an anionic surfactant.

FIGS. 14 to 20 are views for describing a method of manufacturing an optical path control member according to an embodiment.

FIGS. 21 and 22 are cross-sectional views of a display device to which an optical path control member according to an embodiment is applied.

FIGS. 23 to 25 are views for describing one embodiment of the display device to which the optical path control member according to the embodiment is applied.

### MODES OF THE INVENTION

Hereinafter, embodiments of the present invention will be described in detail with reference to the accompanying drawings. However, the spirit and scope of the present invention is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless In detail stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements.

In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements.

Furthermore, when expressed as “on (over)” or “under (below)”, it may include not only the upper direction but also the lower direction based on one element.

Hereinafter, an optical path control member according to an embodiment will be described with reference to drawings. The optical path control member described below relates to a switchable optical path control member driven in various modes according to electrophoretic particles moving by application of a voltage.

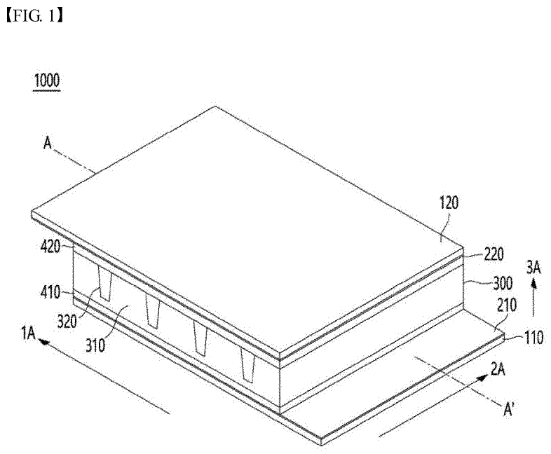

Referring to FIGS. 1 to 4, an optical path control member 1000 according to an embodiment may include a first substrate 110, a second substrate 120, a first electrode 210, a second electrode 220, and a light conversion part 300.

The first substrate 110 may support the first electrode 210. The first substrate 110 may be rigid or flexible.

In addition, the first substrate 110 may be transparent. For example, the first substrate 110 may include a transparent substrate capable of transmitting light.

The first substrate 110 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example, but the embodiment is not limited thereto.

In addition, the first substrate 110 may be a flexible substrate having flexible characteristics.

Further, the first substrate 110 may be a curved or bended substrate. That is, the optical path control member including the first substrate 110 may also be formed to have flexible, curved, or bent characteristics. Accordingly, the optical path control member according to the embodiment may be changed to various designs.

The first substrate 110 may extend in a first direction 1A, a second direction 2A, and a third direction 3A.

In detail, the first substrate 110 may include the first direction 1A corresponding to a length or width direction of the first substrate 110, a second direction 2A extending in a direction different from the first direction 1A and corresponding to the length or width direction of the first substrate 110, and a third direction 3A extending in a direction different from the first direction 1A and the second direction 2A and corresponding to a thickness direction of the first substrate 110.

For example, the first direction 1A may be defined as the length direction of the first substrate 110, the second direction 2A may be defined as the width direction of the first substrate 110 perpendicular to the first direction 1A, and the third direction 3A may be defined as the thickness direction of the first substrate 110. Alternatively, the first direction 1A may be defined as the width direction of the first substrate 110, the second direction 2A may be defined as the length direction of the first substrate 110 perpendicular to the first direction 1A, and the third direction 3A may be defined as the thickness direction of the first substrate 110.

Hereinafter, for convenience of description, the first direction 1A will be described as the length direction of the first substrate 110, the second direction 2A will be described as the width direction of the first substrate 110, and the third directions 3A will be described as the thickness direction of the first substrate 110.

The first electrode 210 may be disposed on one surface of the first substrate 110. In detail, the first electrode 210 may be disposed on an upper surface of the first substrate 110. That is, the first electrode 210 may be disposed between the first substrate 110 and the second substrate 120.

The first electrode 210 may include a transparent conductive material. For example, the first electrode 210 may include a conductive material having a light transmittance of about 80% or more.

As an example, the first electrode 210 may include a metal oxide such as indium tin oxide, indium zinc oxide, copper oxide, tin oxide, zinc oxide, titanium oxide, etc.

The first electrode 210 may have a thickness of 0.05 μm to 2 μm.

Alternatively, the first electrode 210 may include various metals to realize low resistance. For example, the first electrode 210 may include at least one metal of chromium (Cr), nickel (Ni), copper (Cu), aluminum (Al), silver (Ag), molybdenum (Mo). Gold (Au), titanium (Ti), and alloys thereof.

Referring to FIG. 3, the first electrode 210 may be disposed on the entire surface of one surface of the first substrate 110. In detail, the first electrode 210 may be disposed as a surface electrode on one surface of the first substrate 110. However, the embodiment is not limited thereto, and the first electrode 210 may be formed of a plurality of pattern electrodes having a uniform pattern such as a mesh or stripe shape.

For example, the first electrode 210 may include a plurality of conductive patterns. In detail, the first electrode 210 may include a plurality of mesh lines crossing each other and a plurality of mesh openings formed by the mesh lines.

Accordingly, even though the first electrode 210 includes a metal, the first electrode 210 is not visually recognized from the outside, so that visibility may be improved. In addition, the light transmittance is increased by the openings, so that the brightness of the optical path control member according to the embodiment may be improved.

The second substrate 120 may be disposed on the first substrate 110. In detail, the second substrate 120 may be disposed on the first electrode 210 on the first substrate 110.

The second substrate 120 may include a material capable of transmitting light. The second substrate 120 may include a transparent material. The second substrate 120 may include a material the same as or similar to that of the first substrate 110 described above.

For example, the second substrate 120 may include glass, plastic, or a flexible polymer film. For example, the flexible polymer film may be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS). This is only an example, but the embodiment is not limited thereto.

In addition, the second substrate 120 may be a flexible substrate having flexible characteristics.

Further, the second substrate 120 may be a curved or bended substrate. That is, the optical path control member including the second substrate 120 may also be formed to have flexible, curved, or bent characteristics. Accordingly, the optical path control member according to the embodiment may be changed to various designs.

The second substrate 120 may also extend in the first direction 1A, the second direction 2A, and the third direction 3A in the same manner as the first substrate 110 described above.

In detail, the second substrate 120 may include the first direction 1A corresponding to a length or width direction of the second substrate 120, the second direction 2A extending in a direction different from the first direction 1A and corresponding to the length or width direction of the second substrate 120, and the third direction 3A extending in the direction different from the first direction 1A and the second direction 2A and corresponding to the thickness direction of the second substrate 120.

For example, the first direction 1A may be defined as the length direction of the second substrate 120, the second direction 2A may be defined as the width direction of the second substrate 120 perpendicular to the first direction 1A, and the third direction 3A may be defined as the thickness direction of the second substrate 120.

Alternatively, the first direction 1A may be defined as the width direction of the second substrate 120, the second direction 2A may be defined as the length direction of the second substrate 120 perpendicular to the first direction 1A, and the third direction 3A may be defined as the thickness direction of the second substrate 120.

Hereinafter, for convenience of description, the first direction 1A will be described as the length direction of the second substrate 120, the second direction 2A the second direction 2A will be described as the width direction of the second substrate 120, and the third directions 3A will be described as the thickness direction of the second substrate 120.

The second electrode 220 may be disposed on one surface of the second substrate 120. In detail, the second electrode 220 may be disposed on a lower surface of the second substrate 120. That is, the second electrode 220 may be disposed on one surface of the second substrate 120 in which the second substrate 120 and the first substrate 110 face each other. That is, the second electrode 220 may be disposed to face the first electrode 210 on the first substrate 110. That is, the second electrode 220 may be disposed between the first electrode 210 and the second substrate 120.

The second electrode 220 may include a material the same as or similar to that of the first substrate 110 described above.

The second electrode 220 may include a transparent conductive material. For example, the second electrode 220 may include a conductive material having a light transmittance of about 80% or more. As an example, the second electrode 220 may include a metal oxide such as indium tin oxide, indium zinc oxide, copper oxide, tin oxide, zinc oxide, titanium oxide, etc.

The second electrode 220 may have a thickness of about 0.1 μm to about 0.5 μm.

Alternatively, the second electrode 220 may include various metals to realize low resistance. For example, the second electrode 220 may include at least one metal of chromium (Cr), nickel (Ni), copper (Cu), aluminum (Al), silver (Ag), molybdenum (Mo). gold (Au), titanium (Ti), and alloys thereof.

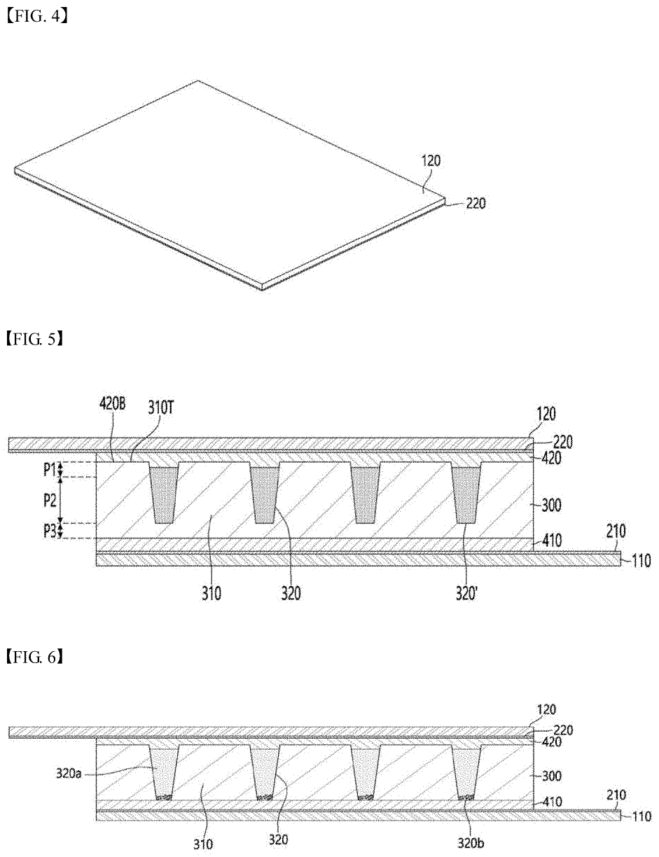

Referring to FIG. 4, the second electrode 220 may be disposed on the entire surface of one surface of the second substrate 120. In detail, the second electrode 220 may be disposed as a surface electrode on one surface of the second substrate 120. However, the embodiment is not limited thereto, and the second electrode 220 may be formed of a plurality of pattern electrodes having a uniform pattern such as a mesh or stripe shape.

For example, the second electrode 220 may include a plurality of conductive patterns. In detail, the second electrode 220 may include a plurality of mesh lines crossing each other and a plurality of mesh openings formed by the mesh lines.

Accordingly, even though the second electrode 220 includes a metal, the second electrode 220 is not visually recognized from the outside, so that visibility may be improved. In addition, the light transmittance is increased by the openings, so that the brightness of the optical path control member according to the embodiment may be improved.

The first substrate 110 and the second substrate 120 may have sizes corresponding to each other. The first substrate 110 and the second substrate 120 may have sizes the same as or similar to each other.

In detail, a first length extending in the first direction 1A of the first substrate 110 may have a size the same as or similar to a second length L2 extending in the first direction 1A of the second substrate 120.

For example, the first length and the second length may have a size of 300 mm to 400 mm.

In addition, a first width extending in the second direction 2A of the first substrate 110 may have a size the same as or similar to a second width extending in the second direction 2A of the second substrate 120.

For example, the first width and the second width may have a size of 150 mm to 200 mm.

In addition, a first thickness extending in the third direction 3A of the first substrate 110 may have a size the same as or similar to a second thickness extending in the third direction 3A of the second substrate 120.

For example, the first thickness and the second thickness may have a size of 30 μm to 200 μm.

Referring to FIG. 1, the first substrate 110 and the second substrate 120 may be disposed to be misaligned from each other.

In detail, the first substrate 110 and the second substrate 120 may be disposed at positions misaligned from each other in the first direction 1A. In detail, the first substrate 110 and the second substrate 120 may be disposed so that side surfaces of the substrates are misaligned from each other.

Accordingly, the first substrate 110 may be disposed to protrude in one direction in the first direction 1A, and the second substrate 120 may be disposed to protrude in the other direction in the second direction 2A.

That is, the first substrate 110 may include a first protrusion protruding in one direction in the first direction 1A, and the second substrate 110 may include a second protrusion protruding in the other direction in the first direction 1A.

Accordingly, the optical path control member 1000 may include a region where the first electrode 210 is exposed on the first substrate 110 and a region where the second electrode 220 is exposed under the second substrate 120.

That is, the first electrode 210 disposed on the first substrate 110 may be exposed at the first protrusion, and the second electrode 220 disposed under the second substrate 120 may be exposed at the second protrusion.

The first electrode 210 and the second electrode 220 exposed at the protrusions may be connected to an external printed circuit board through a connection portion that will be described below.

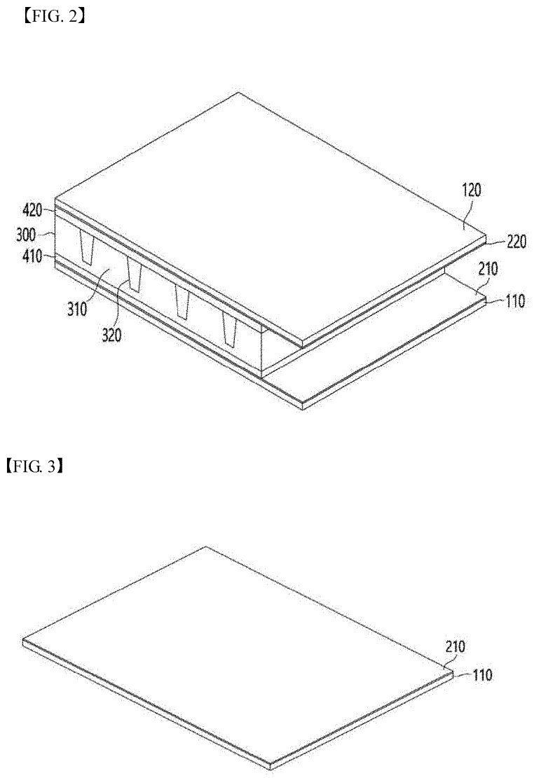

Alternatively, referring to FIG. 2, the first substrate 110 and the second substrate 120 may be disposed at positions corresponding to each other. In detail, the first substrate 110 and the second substrate 120 may be disposed so that each side surface corresponds to each other.

Accordingly, the first substrate 110 may be disposed to protrude in one direction of the first direction 1A, and the second substrate 120 may also be disposed to protrude in one direction of the first direction 1A, that is, in the same direction as the first substrate 110.

That is, the first substrate 110 may include the first protrusion protruding in one direction in the first direction 1A, and the second substrate may also include the second protrusion protruding in one direction in the first direction 1A.

That is, the first protrusion and the second protrusion may protrude in the same direction.

Accordingly, the optical path control member 1000 may include the region where the first electrode 210 is exposed on the first substrate 110 and the region where the second electrode 220 is exposed under the second substrate 120.

That is, the first electrode 210 disposed on the first substrate 110 may be exposed at the first protrusion, and the second electrode 220 disposed under the second substrate 120 may be exposed at the second protrusion.

The first electrode 210 and the second electrode 220 exposed at the protrusions may be connected to the external printed circuit board through the connection portion that will be described below.

The light conversion part 300 may be disposed between the first substrate 110 and the second substrate 120. In detail, the light conversion part 300 may be disposed between the first electrode 210 and the second electrode 220.

An adhesive layer or a buffer layer may be disposed between at least one of between the light conversion part 300 and the first substrate 110 or between the light conversion part 300 and the second substrate 120, and the first substrate 110, the second substrate 120, and the light conversion part 300 may be adhered to each other by the adhesive layer and/or the buffer layer.

The light conversion part 300 may include a plurality of partition wall portions and accommodation portions. Light conversion particles that move according to application of a voltage may be disposed in the accommodation portion, and light transmission characteristics of the optical path control member may be changed by the light conversion particles.

A size of the light conversion part 300 may be smaller than a size of at least one of the first substrate 110 and the second substrate 120.

In detail, a length of the light conversion part 300 in the first direction may be smaller than a length of at least one of the first substrate 110 and the second substrate 120 in the first direction.

In addition, a width of the light conversion part 300 in the second direction may be the same as or smaller than a width of at least one of the first substrate 110 and the second substrate 120 in the second direction.

In addition, at least one of both ends of the first substrate 110 and the second substrate 120 in the first direction may be disposed outside both ends of the light conversion part 300 in the first direction.

Accordingly, a sealing portion (not shown in the drawing) may be easily disposed, and the adhesive properties of the sealing portion may be improved.

An optical path control member according to an embodiment will be described with reference to FIG. 5.

The optical path control member according to the embodiment may include a light conversion material. For example, the light conversion material 320′ may be an EPD ink. In order to accommodate the light conversion material 320′ and prevent overflow thereof, the light conversion part 300 may be used. The light conversion part 300 may include an accommodation portion 320 for accommodating the light conversion material 320′ and a partition wall portion 310 for preventing the light conversion material 320′ from overflowing.

The light conversion part 300 may be formed of a photocurable resin. For example, the light conversion part 300 may be formed by imprinting the photocurable resin. That is, the partition wall portion 310 and the accommodation portion 320 may be formed of the photocurable resin.

In detail, the partition wall portion 310 may include a resin material. For example, the partition wall portion 310 may include a photocurable resin material. As an example, the partition wall portion 310 may include a urethane resin or the like.

The photocurable resin may include urethane acrylate, an acrylate monomer, isobornyl acrylate, an additive, a photoinitiator, and acryloylmorpholine. For example, the photoinitiator may include 1-Hydroxycyclohexyl Phenylmethanone.

The photocurable resin may include an oligomer, a monomer, a photopolymerization initiator, and an additive. The photocurable resin may form the light conversion part by reaction of a polymer-type prepolymer, a polyfunctional monomer as a diluent, and a photopolymerization initiator.

Here, the additive may be various materials added to improve the driving speed of a device. For example, the additive may be a material that may be applied to the photocurable resin to increase the driving speed of the EPD ink. Here, the additive may refer to various materials for improving releasability or electrical characteristics of the photocurable resin. For example, the additive may refer to various materials including a release additive and/or an antistatic agent.

However, when such an additive is excessively added, a problem that haze increases at an interface of the resin layer and transmittance decreases may occur. In addition, the additive has a property of moving to a surface of the resin over time. Such movement of the additive may cause a problem of deteriorating the optical characteristics of the optical path control member. In addition, the movement of the additive may deteriorate adhesion between the additive and the partition wall portion.

The embodiment may optimize a content of the additive included in the photocurable resin forming the partition wall portion in order to reduce the movement of the additive. Accordingly, the embodiment may improve optical characteristics by reducing haze and increasing transmittance. In addition, the embodiment may improve the adhesion between the adhesive layer and the partition wall portion by optimizing the content of the additive.

With reference to Table 1, changes in haze and transmittance according to types and contents of additives in Examples 1 to 3 will be described.

When a weight of the photocurable resin is 100 wt %, the additive may be included in an amount of 5.0 wt % or less. In detail, when a weight of the photocurable resin is 100 wt %, the additive may be included in 2.0 wt % to 3.0 wt %. In the embodiment, since the additive in the photocurable resin is included in an amount of 5.0 wt % or less, the amount of the additive moving to the surface of the resin may be reduced.

The additive may include the antistatic agent in an amount of 1.5 wt % to 3.0 wt %. For example, the additive may include the antistatic agent in an amount of 2.0 wt % to 3.0 wt %. For example, the additive may include the antistatic agent in an amount of 2.4 wt % to 2.7 wt %.

In Example 1, the photocurable resin forming the light conversion part may include the antistatic agent as an additive in an amount of 2.0 wt % to 3.0 wt %.

The antistatic agent may be included in the photocurable resin to improve conductivity. The antistatic agent may help improve electrical conductivity by lowering a volume resistance and surface resistance. The antistatic agent may use a material or an ionic compound having high charge mobility to implement antistatic effect by moving an electric charge accumulated on a surface or inside of a component to an external conductive material (moisture). That is, the antistatic agent may improve driving characteristics of the electric charge transferred to the surface.

When the antistatic agent is included in the photocurable resin in an amount of 2.0 wt % to 3.0 wt %, it is possible to prevent movement of the additive to the resin surface, thereby reducing haze. In detail, when the antistatic agent is contained in an amount of 2.0 wt % to 3.0 wt % in the photocurable resin, the haze may be 9% or less.

For example, the photocurable resin of the embodiment may include the antistatic agent in an amount of 2.0 wt % to 3.0 wt %, so that the haze may be 5% or less. For example, the photocurable resin of the embodiment may include the antistatic agent in an amount of 2.0 wt % to 3.0 wt %, so that the haze may be 3% or less.

When the antistatic agent is included in the photocurable resin in an amount of 2.0 wt % to 3.0 wt %, a lateral transmittance of the optical path control member and a display device including the same may be increased. In the embodiment, the antistatic agent may be included in the photocurable resin in an amount of 2.0 wt % to 3.0 wt %, thereby improving the lateral transmittance to 30% or more. In detail, in the embodiment, the antistatic agent may be included in the photocurable resin in an amount of 2.0 wt % to 3.0 wt %, thereby improving the lateral transmittance to 33% to 37%.

Here, the lateral transmittance is measured in a share mode and may refer to a luminance value measured when the device is positioned at 45 degrees. That is, the lateral transmittance is that the luminance value of the device positioned at the 45 degrees is measured in a measuring device.

In detail, the lateral transmittance of the optical path control member may be defined as a light transmittance measured by (B/A)*100 after measuring a luminance (A) of light emitted from a light source in a state in which the optical path control member is not disposed and a luminance (B) of light emitted at an angle of 45° through the optical path control member in the light source in a state in which the optical path control member is disposed on the light source.

When the antistatic agent is included in an amount greater than 3.0 wt %, there is a problem of deteriorating the optical characteristics of the resin and deteriorating the adhesive performance. In detail, when the antistatic agent is included in the amount of greater than 3.0 wt % in the photocurable resin, haze of the resin may be increased, and adhesion between the light conversion part and the adhesive layer may be deteriorated.

As an example, when the antistatic agent is included in the amount of greater than 3.0 wt %, the haze may rapidly increase to 60% to 70%. In addition, when the antistatic agent is included in the amount greater than 3.0 wt %, the lateral transmittance may be less than 30%. In detail, when the antistatic agent is included in the amount of more than 3.0 wt %, the lateral transmittance may show 17% to 26%.

When the antistatic agent is included in an amount of less than 2.0 wt %, the driving speed of the optical path control member and the display device including the same may be reduced.

The antistatic agent may include a surfactant.

The antistatic agent may include at least one of conductive carbon, a conductive inorganic material such as metal particles, a conductive polymer, and a surfactant. For example, the embodiment may include the surfactant as an antistatic agent. Accordingly, the embodiment may increase the driving speed even by using a small amount of additive. In addition, the surfactant has an advantage of low cost. The conductive inorganic material has disadvantages that a mixing process is difficult, particles may be generated, and the price is high. In addition, the conductive polymer has a problem in color realization and the like.

The surfactant may include at least one of a nonionic surfactant, a cationic surfactant, an anionic surfactant, and an amphoteric surfactant. The nonionic surfactant may include an amine-based surfactant or a glycerin-based surfactant. The cationic surfactant may include a quaternary ammonium salt. The anionic surfactant may include sulfonate and phosphate. The amphoteric surfactant may include betaine.

Here, the additive may further include a non-reactive release additive having a form of a siloxane product. As an example, the non-reactive release additive may be a Si-containing material such as PDMS.

The non-reactive release additive may include a material in which a functional group is bonded to polydimethylsiloxane. The non-reactive release additive may include a material in which one or more functional groups are bonded to polydimethylsiloxane. The non-reactive release additive may include a material in which two or more functional groups that are the same or different from each other are bonded to polydimethylsiloxane.

The non-reactive release additive may be a functional fluid in which a functional group is bonded to polydimethylsiloxane. In detail, the functional group bonded to a backbone of polydimethylsiloxane may include various materials such as alkyl, aryl, allyl, alkenyl, amido, amino, fluoroalkyl, halide, epoxy, carboxyl, hydroxyl, alkoxy, methylhydrogen, and the like. In addition, copolymer containing Si may include siloxane-urethane copolymer, siloxane-polycaponate copolymer, siloxane-polyester copolymer, siloxane-polyimide copolymer, acryloxymethylsiloxane, p-styrylsiloxane, copolymer of silicone and aldehyde, polysilformal, and the like.

In Example 2, the additive may include the non-reactive release additive in an amount of 0.3 wt % or less.

The photocurable resin of the embodiment may include the non-reactive release additive in an amount of 0.3 wt % or less. For example, the photocurable resin of the embodiment may include the non-reactive release additive in an amount of 0.1 wt % to 0.2 wt %. In detail, in the embodiment, the non-reactive release additive is included in the photocurable resin in an amount of 0.1 wt % to 0.2 wt %, thereby showing a haze value of 9% or less. In detail, in the embodiment, the non-reactive release additive is included in the photocurable resin in an amount of 0.1 wt % to 0.2 wt %, thereby showing a haze value of 5% or less. In detail, in the embodiment, the non-reactive release additive is included in the photocurable resin in an amount of 0.1 wt % to 0.2 wt %, thereby showing a haze value of 3% or less. In addition, in the embodiment, the non-reactive release additive is included in the photocurable resin in an amount of 0.1 wt % to 0.2 wt %, so that the optical path control member and the display device including the same may show a lateral transmittance of 30% or more. In detail, in the embodiment, the non-reactive release additive is included in the photocurable resin in an amount of 0.1 wt % to 0.2 wt %, so that the optical path control member and the display device including the same may show a lateral transmittance of 33% to 37%.

When the non-reactive release additive is included in the photocurable resin in an amount of less than 0.1 wt %, the release property may be deteriorated, and productivity or process efficiency may be deteriorated when the resin layer is formed by imprinting.

When the non-reactive release additive is included in the photocurable resin in an amount of more than 0.3 wt %, haze may rapidly increase. As an example, when the non-reactive release additive is included in the photocurable resin in an amount of more than 0.3 wt %, the haze may be 40% to 50%.

In Example 3, the photocurable resin forming the light conversion part may include an antistatic agent and a non-reactive release additive in an amount of 2.4 wt % to 2.8 wt % as an additive. For example, in the embodiment, the photocurable resin may include 0.05 wt % to 0.2 wt % of a non-reactive release additive and 2.4 wt % to 2.7 wt % of an antistatic agent as an additive. In Example 2, as the two additives are added in an optimal content, all of the releasability, adhesion, driving speed, and transmittance may be improved. In Example 3, a lateral transmittance value may be improved compared to Example 1 or Example 2 in which any one of the release additive and the antistatic agent is added.

In the embodiment, an antistatic agent and a non-reactive release additive as an additive may be included in the photocurable resin in an amount of 2.4 wt % to 2.8 wt %, so that the haze may be 9% or less. For example, in the embodiment, the antistatic agent and the non-reactive release additive as the additive may be included in the photocurable resin in an amount of 2.4 wt % to 2.8 wt %, so that the haze may be 5% or less. For example, in the embodiment, the antistatic agent and the non-reactive release additive as the additive may be included in the photocurable resin in an amount of 2.4 wt % to 2.8 wt %, so that the haze may be 3% or less.

In the embodiment, the antistatic agent and the non-reactive release additive as the additive may be included in the photocurable resin in an amount of 2.4 wt % to 2.8 wt %, so that the lateral transmittance of the optical path control member and the display device including the same may be 30% or more.

For example, in the embodiment, the antistatic agent and the non-reactive release additive as the additive may be included in the photocurable resin in an amount of 2.4 wt % to 2.8 wt %, so that the lateral transmittance of the optical path control member and the display device including the same may be 35% or more. For example, in the embodiment, the antistatic agent and the non-reactive release additive as the additive may be included in the photocurable resin in an amount of 2.4 wt % to 2.8 wt %, so that the lateral transmittance of the optical path control member and the display device including the same may be 37% to 41%.

Meanwhile, when the additive is not included, it is possible to show a problem that the lateral transmittance of the display device including the photocurable resin may be less than 5%.

TABLE 1

| | | | | Comparative |
|---|---|---|---|---|
| | Example 1 | Example 2 | Example 3 | Example 1 |
| Non-reactive | — | 0.1~0.2 | 0.05~0.2 | — |
| release additive | | | | |
| (wt %) | | | | |
| Antistatic agent | 2.0~3.0 | — | 2.4~2.7 | — |
| (wt %) | | | | |
| Haze (%) | 2.3~8.6 | 1.5~5.0 | 1.9~8.5 | — |
| Lateral | 33~37 | 33~37 | 37~41 | 3.2~4.8 |
| transmittance | | | | |
| (%) | | | | |

In the embodiment, it can be confirmed that the content of the additive according to the position of the partition wall portion by measuring XPS from an interface between an upper surface 310T of the partition wall portion and a lower surface 420B of the adhesive layer in a depth direction of the partition wall portion. The partition wall portion 310 may be divided into a first region that is a surface part of the resin, a second region that is an intermediate part, and a third region that is a base layer part according to the depth thereof. In detail, the partition wall portion may include a first region P1 from the upper surface 310T of the partition wall portion to 30 μm in the depth direction, a second region P2 from 30 μm to 60 μm from the upper surface of the partition wall portion in the depth direction, and a third region P3 from 60 μm to 95 μm from the upper surface of the partition wall portion in the depth direction.

In an embodiment, an Si content in the first region may be reduced. Accordingly, it is possible to prevent film removal of the adhesive layer on a surface of the resin layer.

Details of the light conversion part 300 will be described in detail below.

Referring to FIGS. 5 to 9, the light conversion part 300 may include a partition wall portion 310, and an accommodation portion 320.

The partition wall portion 310 may be defined as a partition wall portion dividing the accommodation portion. That is, the partition wall portion 310 may transmit light as a barrier region dividing a plurality of accommodation portions. In addition, the accommodation portion 320 may be defined as a variable region where the accommodation portion 320 is switched to a light blocking part and a light transmitting part according to application of a voltage.

The partition wall portion 310 and the accommodation portion 320 may be alternately disposed with each other. The partition wall portion 310 and the accommodation portion 320 may be disposed to have different widths. For example, a width of the partition wall portion 310 may be greater than that of the accommodation portion 320.

The partition wall portion 310 and the accommodation portion 320 may be alternately disposed with each other. In detail, the partition wall portion 310 and the accommodation portion 320 may be alternately disposed with each other. That is, each of the partition wall portions 310 may be disposed between the accommodation portions 320 adjacent to each other, and each of the accommodation portions 320 may be disposed between the adjacent partition wall portions 310.

The partition wall portion 310 may include a transparent material. The partition wall portion 310 may include a material that may transmit light.

The partition wall portion 310 may transmit light incident on any one of the first substrate 110 and the second substrate 120 toward another substrate.

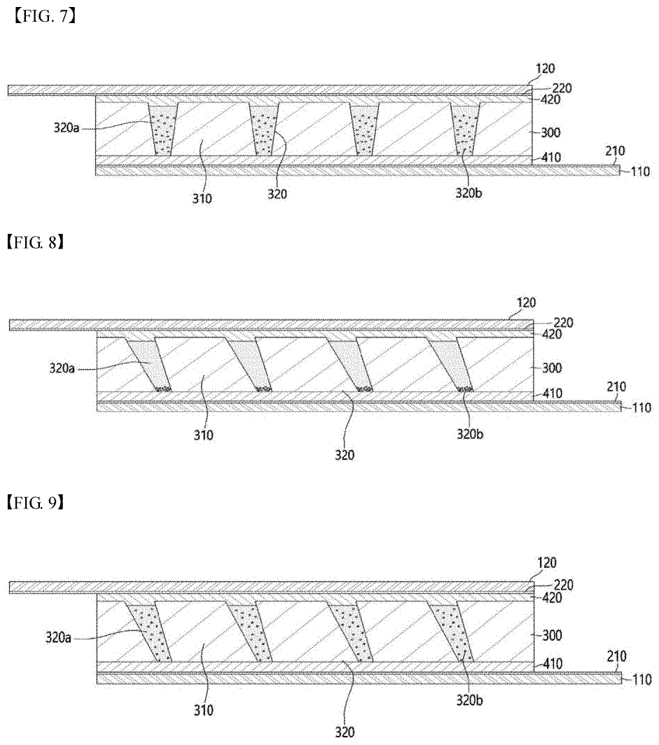

For example, in FIGS. 6 and 9, light may be emitted from the first substrate 110 by a light source disposed under the first substrate 110, and the light may be incident toward the second substrate 120. In this case, the partition wall portion 310 may transmit the light, and the transmitted light may move toward the second substrate 120.

The accommodation portion 320 may include the dispersion liquid 320a and the light conversion particles 320b. In detail, the accommodation portion 320 may be filled by injecting the dispersion liquid 320a. A plurality of light conversion particles 320b may be dispersed in the dispersion liquid 320a.

The dispersion liquid 320a may be a material for dispersing the light conversion particles 320b. The dispersion liquid 320a may include a transparent material. The dispersion liquid 320a may include a non-polar solvent. In addition, the dispersion liquid 320a may include a material capable of transmitting light. For example, the dispersion liquid 320a may include at least one of a halocarbon-based oil, a paraffin-based oil, and isopropyl alcohol.

The light conversion particles 320b may be disposed to be dispersed in the dispersion liquid 320a. In detail, the plurality of light conversion particles 320b may be disposed to be spaced apart from each other in the dispersion liquid 320a.

The dispersion liquid 320a may further include an additive. The additive included in the dispersion liquid 320a will be described in detail below.

The light conversion particles 320b may include a material capable of absorbing light. That is, the light conversion particles 320b may be light absorbing particles. The light conversion particles 320b may have a color. For example, the light conversion particles 320b may have a black-based color. As an example, the light conversion particles 320b may include carbon black.

The light conversion particles 320b may have a polarity by charging a surface thereof. For example, the surface of the light conversion particles 320b may be charged with a negative (−) charge. Accordingly, according to the application of the voltage, the light conversion particles 320b may move toward the first electrode 210 or the second electrode 220.

The light transmittance of the accommodation portion 320 may be changed by the light conversion particles 320b. In detail, the accommodation portion 320 may be switched to the light blocking part and the light transmitting part by changing the light transmittance due to the movement of the light conversion particles 320b. That is, the accommodation portion 320 may change the transmittance of light passing through the accommodation portion 320 by dispersion and aggregation of the light conversion particles 320b disposed inside the dispersion liquid 320a.

For example, the optical path control member according to the embodiment may be converted from a first mode to a second mode or from the second mode to the first mode by a voltage applied to the first electrode 210 and the second electrode 220.

In detail, in the optical path control member according to the embodiment, the accommodation portion 320 becomes the light blocking part in the first mode, and light of a specific angle may be blocked by the accommodation portion 320. That is, a viewing angle of the user viewing from the outside is narrowed, so that the optical path control member may be driven in a privacy mode.

In addition, in the optical path control member according to the embodiment, the accommodation portion 320 becomes the light transmitting part in the second mode, and in the optical path control member according to the embodiment, light may be transmitted through both the partition wall portion 310 and the accommodation portion 320. That is, the viewing angle of the user viewing from the outside may be widened, so that the optical path control member may be driven in a public mode.

Switching from the first mode to the second mode, that is, the conversion of the accommodation portion 320 from the light blocking part to the light transmitting part may be realized by movement of the light conversion particles 320b of the accommodation portion 320. That is, the light conversion particles 320b may have a charge on the surface thereof and may move toward the first electrode or the second electrode according to the application of a voltage according to characteristics of the charge. That is, the light conversion particles 320b may be electrophoretic particles

In detail, the accommodation portion 320 may be electrically connected to the first electrode 210 and the second electrode 220.

In this case, when a voltage is not applied to the optical path control member from the outside, the light conversion particles 320b of the accommodation portion 320 are uniformly dispersed in the dispersion liquid 320a, and the accommodation portion 320 may block light by the light conversion particles. Accordingly, in the first mode, the accommodation portion 320 may be driven as the light blocking part.

Alternatively, when a voltage is applied to the optical path control member from the outside, the light conversion particles 320b may move. For example, the light conversion particles 320b may move toward one end or the other end of the accommodation portion 320 by a voltage transmitted through the first electrode 210 and the second electrode 220. That is, the light conversion particles 320b may move from the accommodation portion 320 toward the first electrode 210 or the second electrode 220.

In detail, when a voltage is applied to the first electrode 210 and/or the second electrode 220, an electric field is formed between the first electrode 210 and the second electrode 220, and the light conversion particles 320b charged with the negative charge may move toward a positive electrode of the first electrode 210 and the second electrode 220 using the dispersion liquid 320a as a medium.

That is, when the voltage is applied to the first electrode 210 and/or the second electrode 220, as shown in FIG. 8, the light conversion particles 320b may move toward the first electrode 210 in the dispersion liquid 320a. That is, the light conversion particles 320b may move in one direction, and the accommodation portion 320 may be driven as the light transmitting part.

Alternatively, when the voltage is not applied to the first electrode 210 and/or the second electrode 220, as shown in FIG. 9, the light conversion particles 320b may be uniformly dispersed in the dispersion liquid 320a to drive the accommodation portion 320 as the light blocking part.

Accordingly, the optical path control member according to the embodiment may be driven in two modes according to a user's surrounding environment. That is, when the user requires light transmission only at a specific viewing angle, the accommodation portion is driven as the light blocking part, or in an environment in which the user requires high brightness, a voltage may be applied to drive the accommodation portion as the light transmitting part.

Therefore, since the optical path control member according to the embodiment may be implemented in two modes according to the user's requirement, the optical path control member may be applied regardless of the user's environment.

Meanwhile, the accommodation portion may be disposed in a different shape in consideration of driving characteristics and the like.

Referring to FIGS. 6 and 7, in an optical path control member according to another embodiment, both ends of an accommodation portion 320 may be disposed in contact with a buffer layer 410 and an adhesive layer 420 unlike FIG. 5.

For example, a lower portion of the accommodation portion 320 may be disposed in contact with the buffer layer 410, and an upper portion of the accommodation portion 320 may be disposed in contact with the adhesive layer 420.

Accordingly, a distance between the accommodation portion 320 and the first electrode 210 may be reduced, so that the voltage applied from the first electrode 210 may be smoothly transmitted to the accommodation portion 320.

Accordingly, a moving speed of the light conversion particles 320b inside the accommodation portion 320 may be improved, and thus the driving characteristics of the optical path control member may be improved.

In addition, referring to FIGS. 8 and 9, in an optical path control member according to an embodiment, unlike FIGS. 6 and 7, an accommodation portion 320 may be disposed to have a constant inclination angle θ.

In detail, referring to FIGS. 8 and 9, the accommodation portion 320 may be disposed to have an inclination angle θ of greater than 0° to less than 90° with respect to the first substrate 110. In detail, the accommodation portion 320 may extend upward while having an inclination angle θ of greater than 0° to less than 90° with respect to one surface of the first substrate 110.

Accordingly, when the optical path control member is used together with a display panel, moire caused by an overlapping phenomenon between a pattern of the display panel and the accommodation portion 320 of the optical path control member may be alleviated, thereby improving user visibility.

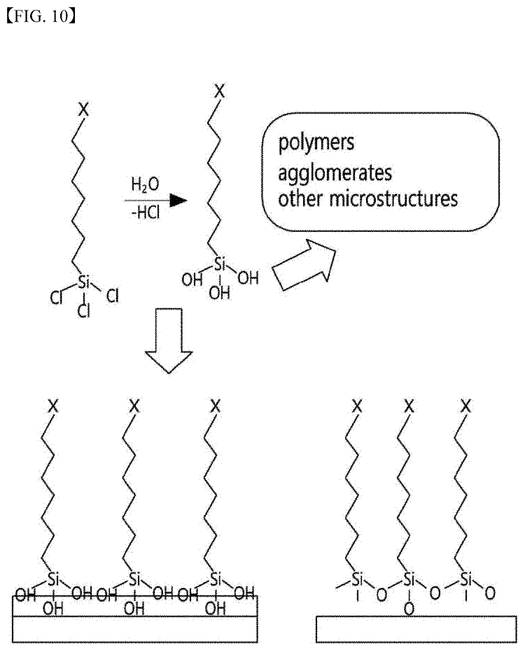

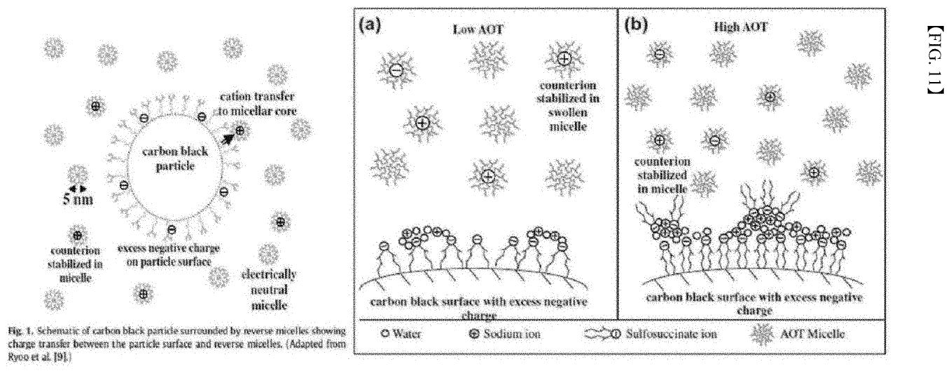

Hereinafter, improvement of a lateral transmittance of the device by including a non-reactive additive in the EPD ink of the embodiment will be described with reference to FIGS. 10 to 13.

The light conversion material 320′ may include light conversion particles and a dispersion liquid.

The light conversion particles may include carbon black.

The dispersion liquid may include an additive and a surfactant. That is, the embodiment may improve the driving performance of the device by including the non-reactive additive in the EPD ink.

FIG. 10 is a view showing an example of a principle that the additive adheres to a surface of the partition wall portion in the dispersion liquid.

The non-reactive additive may include a bond of —Si—. For example, the non-reactive additive may include a PDMS backbone, thereby including repeating bonds of —Si—O—Si—.

When water molecules with a small amount are present in a solvent, a silane group is changed to Si—OH, thereby creating a hydrophobic surface. For example, Si—X bond of the non-reactive additive included in the dispersion liquid may react with the water molecules to change into Si—OH bond.

Polymer aggregates and other microstructures may be positioned around the Si—OH.

In this case, X is illustrated as Cl in FIG. 6A, but the embodiment is not limited thereto and may include various functional groups. For example, in the Si—X bond included in the non-reactive additive, X may include various functional groups including a halogen group such as F and CH3, an alkyl group, an alkoxy group, a hydroxyl group, an alkenyl group, an aryl group, and the like.

Meanwhile, the non-reactive additive may include the Si—OH bond. For example, when a functional group is bonded to the alkoxy group or the hydroxyl group in PDMS, the non-reactive additive may include the Si—OH bond.

For example, a single layer of a silane surface may be formed on the partition wall portion by cross-linking between silane groups and surface adhesion. That is, a micelle may be formed as a monolayer. When the water molecules with a small amount are present in the solvent, the silane group is hydrolyzed to Si—OH and forms a hydrophobic surface as a whole.

The micelle may have a thickness of 1 nm to 500 nm. For example, the micelle may have a thickness of 1 nm to 300 nm. For example, the micelle may have a thickness of 1 nm to 500 nm. Unlike a core-celle, micelles may have a thickness of less than 1 μm.

As an example, the non-reactive additive may include —O—Si— bond, and an oxygen element in the —O—Si— bond may form a chemical bond with a component of the partition wall portion. For example, oxygen included in the non-reactive additive may form a covalent bond with an element on the partition wall portion.

FIG. 11 is a schematic diagram of dispersion of carbon black and formation of micelles.

When an amount of the surfactant in the light conversion material 320′ is large, more surfactants may be attached around the carbon black to form micelles. Accordingly, there is a problem that a charge of the carbon black is reduced and a movement speed is decreased.

Therefore, in the embodiment, the driving performance of the device may be improved by mixing the EPD ink and the non-reactive additive. In detail, when a silane component of the non-reactive additive is moved to the surface of the partition wall portion, a distribution in the solvent may be reduced while forming the surfactant with the micelle in the EPD ink.

Accordingly, movement of carbon black particles in the light conversion material may be facilitated. That is, the carbon black particles in the light conversion material may not be restricted in movement by the surfactant, so that the lateral transmittance in the share mode may be improved.

The dispersion liquid may include a micelle formed by reacting the surfactant with the silane component of the additive.

In the embodiment, various types of micelles may be included. Here, a first, a second, and a third may be used to distinguish different types of micelles.

The first micelle may surround the carbon black in the dispersion liquid. For example, the first micelle may be in a form of surrounding carbon black particles in the dispersion liquid. In detail, the first micelle may surround one carbon black particle in the dispersion liquid. Alternatively, the first micelle may surround two or more carbon black particles in the dispersion liquid. An anionic material may be positioned on a surface of the first micelle.

Accordingly, a plurality of carbon black particles may be included in the dispersion liquid, and each of the plurality of carbon black particles may be surrounded by the first micelle again. Therefore, the plurality of carbon black particles in the dispersion liquid may be dispersed by the first micelle.

The second micelle may surround ions in the dispersion liquid. For example, the second micelle may surround a cationic material present in the dispersion liquid.

The first micelle may stabilize anions. On the other hand, the second micelle may stabilize cations. That is, ions having different polarities may be stabilized in the dispersion liquid by different micelles.

The third micelle may be attached to the surface of the partition wall portion in the dispersion liquid. In detail, the silane component of the non-reactive additive in the EPD ink may move to the surface of the partition wall portion. Accordingly, like a silane surface coating, a —O—Si— component of the non-reactive additive may be bonded to the partition wall portion. The surfactant in the EPD ink may form the micelle with the silane component of the non-reactive additive. Accordingly, a stacking density of the carbon black particles in the share mode may be improved, and thus the lateral transmittance of the device may be improved.

In addition, since a micelle is formed between surfactant molecules present in excess in the EPD ink, and the micelle between such surfactant molecules forms the micelle with the silane, a distribution of the surfactant in the EPD ink may be reduced.

The non-reactive additive of the embodiment may form micelles with various types of surfactants. For example, an elemental portion of —Si— of the non-reactive additive of the embodiment may be capable of forming micelles with various types of surfactants. In detail, the surfactant may form the micelle by itself, regardless of a type, composition, length, molecular weight, functional group, etc. of the surfactant. The surfactant's own micelle may have a head portion and a tail portion. For example, when the head portion is positioned inside the micelle, the tail portion may be positioned outside the micelle. For example, when the tail portion is positioned inside the micelle, the head portion may be positioned outside the micelle.

For example, as the head portion of the surfactant adheres to a periphery of —Si— of the non-reactive additive, it may form a micelle. For example, as the head portion of the surfactant adheres to a periphery of —Si—O— of the non-reactive additive, it may form a micelle. For example, as the head portion of the surfactant adheres to a periphery of —Si—CH3 of the non-reactive additive, it may form a micelle.

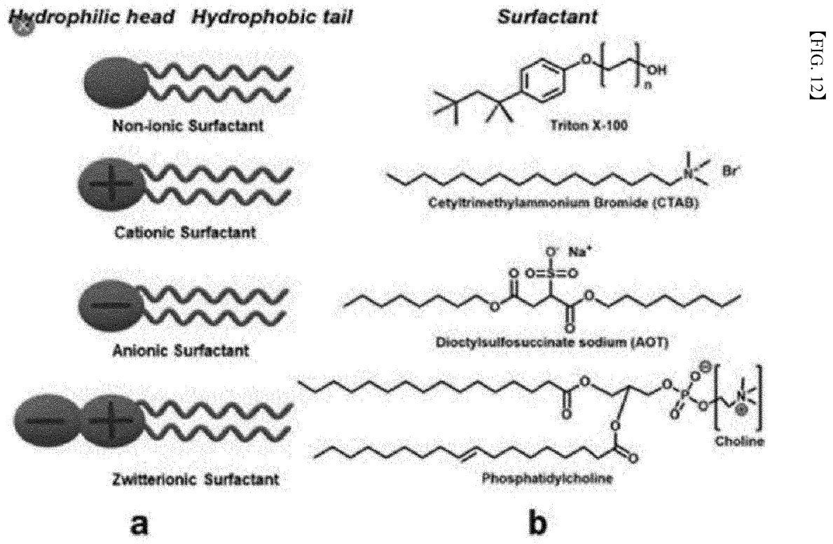

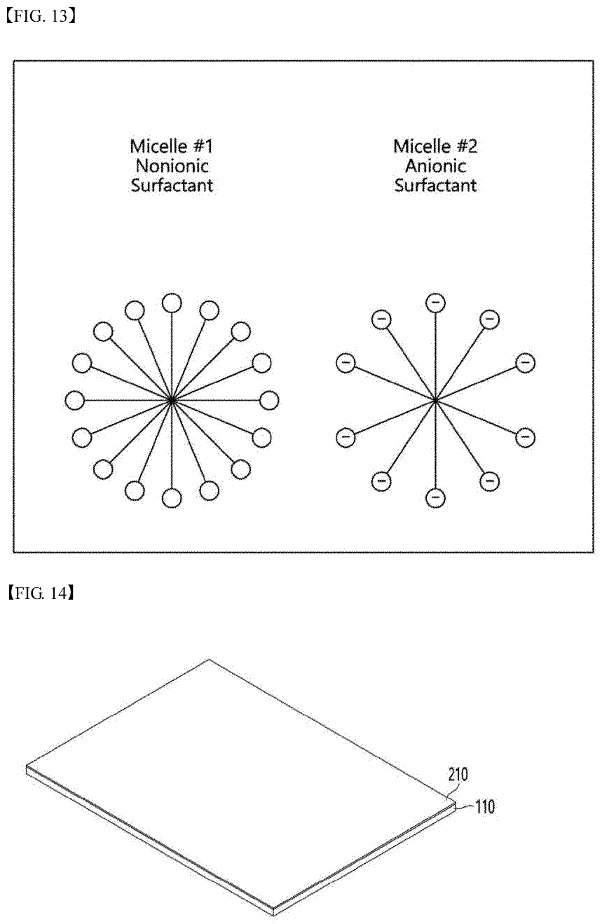

The surfactant will be described in detail with reference to FIGS. 12 and 13.

A structure and type of the surfactant will be described with reference to FIG. 12.

In the embodiment, the surfactant may refer to various types of surfactants. For example, the surfactant may be at least one of a nonionic surfactant, a cationic surfactant and an anionic surfactant, and an amphoteric (zwitterionic) surfactant. Here, the distinction between nonionic, cationic, anionic, and amphoteric properties of the surfactant may be distinguished through a polarity of the head portion.

One compound constituting the surfactant may include both a hydrophilic portion and a hydrophobic portion. Here, the head of the surfactant may refer to a hydrophilic portion of the surfactant. Here, the tail of the surfactant may refer to a hydrophobic portion of the surfactant.

For example, the surfactant may be any one of Triton X-100, CTAB, AOT, and phosphatidylcholine. Of course, the surfactant of the embodiment is not limited thereto and may be various types of materials.

FIG. 13 is a view showing a form of a micelle of the surfactant itself.

For example, in the nonionic surfactant, the tail portion may be positioned inside the micelle and the head portion may be positioned outside the micelle. In this case, the head portion may show nonionic properties. For example, in the anionic surfactant, the tail portion may be positioned inside the micelle and the head portion may be positioned outside the micelle. In this case, the head portion may show anionic properties.

In the embodiment, the carbon black particles in the EPD ink may not be hindered by the surfactant from reducing the charge, so that the moving speed may be high. Accordingly, the embodiment may improve a driving speed of the device.

Referring to Table 2, an evaluation result of the driving characteristic according to the content of the non-reactive additive in the EPD ink will be described.

Here, a standard for the content of the non-reactive additive refers to a content of the additive compared to a case in which a weight of the EPD ink excluding the additive is 100 wt %.

A type of non-reactive additives may include a fluid (oil), a gum, a resin, and an elastomer.

The fluid may be a linear polymer. For example, the fluid may be a Si-containing material such as polydimethylsiloxane (PDMS). Alternatively, the fluid may be a functional fluid. Here, the functional fluid may include a material in which a functional group is bonded to polydimethylsiloxane.

The non-reactive additive may include a material in which one or more functional groups are bonded to polydimethylsiloxane. The non-reactive additive may include a material in which two or more functional groups that are the same or different from each other are bonded to polydimethylsiloxane.

The non-reactive additive may be a functional fluid in which a functional group is bonded to polydimethylsiloxane. In detail, the functional group bonded to the backbone of polydimethylsiloxane may include various materials such as alkyl, aryl, allyl, alkenyl, amido, amino, fluoroalkyl, halide, epoxy, carboxyl, hydroxyl, alkoxy, methylhydrogen, and the like. In addition, the copolymer containing Si may include siloxane-urethane copolymer, siloxane-polycaponate copolymer, siloxane-polyester copolymer, siloxane-polyimide copolymer, acryloxymethylsiloxane, p-styrylsiloxane, copolymer of silicone and aldehyde, polysilformal, and the like.

The non-reactive additive in which a functional group is bonded to polydimethylsiloxane may be an organic modification of a linear polydimethylsiloxane backbone.

The gum may refer to a linear polymer of ultra-high molecular.

The resin is a polymer having a three-dimensional siloxane structure and may refer that there are three reactive groups.

The elastomer may be in a state in which silane/siloxane is cross-linked to form a network.

TABLE 2

| | Category | | | | | | | | |
|---|---|---|---|---|---|---|---|---|---|
| | Comparative | | | | | | | | |
| | Example 2 | Example 4 | | | Example 5 | | | Example 6 | |
| Sample | — | A-1 | A-2 | A-3 | B-1 | B-2 | C-1 | C-2 | C-3 |
| Non-reactive | — | 0.3 | 0.5 | 1 | 0.3 | 0.5 | 0.3 | 0.5 | 1.5 |
| additive (wt %) | | | | | | | | | |
| Device lateral | 4.4 | 33.1 | 42.3 | 46.2 | 36.0 | 45.1 | 39.2 | 41.8 | 45.9 |
| transmittance | | | | | | | | | |
| (share mode, %) | | | | | | | | | |

Comparative Example 2 is a photocurable resin that does not include a non-reactive additive. Here, the photocurable resin is a polyurethane-based material.

Example 4 is PDMS to which an alkyl-based functional group is bonded.

Example 5 is PDMS to which a fluoroalkayl-based functional group is bonded.

Example 6 is a siloxane-urethane copolymer.

In Examples 4 to 6, as the non-reactive additive is included in an amount of 0.1 wt % to 20 wt % based on 100 wt % of the dispersion liquid, it can be confirmed that the lateral transmittance of the device measured in the share mode is 30% or more.

For example, in the embodiment, the non-reactive additive may be included in an amount of 0.1 wt % to 10 wt % based on 100 wt % of the dispersion liquid, and thus it can be confirmed that the lateral transmittance of the device measured in the share mode is 30% or more.

For example, in the embodiment, the non-reactive additive may be included in an amount of 0.1 wt % to 5 wt % based on 100 wt % of the dispersion liquid, and thus it can be confirmed that the lateral transmittance of the device measured in the share mode is 30% or more.

Here, the lateral transmittance is measured in the share mode and may refer to a luminance value measured when the device is positioned at 45 degrees. That is, the lateral transmittance is that the luminance value of the device positioned at the 45 degrees is measured in a measuring device.

That is, in the present invention, the non-reactive additive may be contained in the EPD ink in order to improve the driving speed of the device. Accordingly, dispersibility between carbon black particles in the EPD ink may be improved. In addition, the driving speed may be improved due to the ease of movement of the carbon black in the EPD ink. In addition, the lateral transmittance of the device in the share mode may be improved.

Meanwhile, the EPD ink according to the embodiment may include only a surfactant.

In detail, the EPD ink may include a surfactant that reacts with the non-reactive additive.

In addition, the non-reactive additive reacting with the surfactant may be disposed on the partition wall portion. In detail, the non-reactive additive that reacts with the surfactant to form the micelle may be disposed on the surface of the partition wall portion. In more detail, the non-reactive additive that reacts with the surfactant to form the micelle may be formed on the surface of the partition wall portion.

Therefore, the embodiment may improve the driving performance of the device by disposing the non-reactive additive on the surface of the partition wall portion in contact with the EPD ink. In detail, the non-reactive additive on the surface of the partition wall portion may reduce the distribution in the solvent while forming the micelle with the surfactant in the EPD ink.

That is, the surfactant in the EPD ink may form the micelle with the silane component of the non-reactive additive. Accordingly, the stacking density of carbon black particles in the share mode may be improved, and thus the lateral transmittance of the device may be improved.

Hereinafter, a method of manufacturing an optical path control member according to an embodiment will be described with reference to FIGS. 14 to 20.

Referring to FIG. 14, a first substrate 110 and an electrode material for forming a first electrode are prepared. Then, the first electrode may be formed by coating or depositing the electrode material on one surface of the first substrate. In detail, the electrode material may be formed on the entire surface of the first substrate 110. Accordingly, the first electrode 210 formed as a surface electrode may be formed on the first substrate 110.

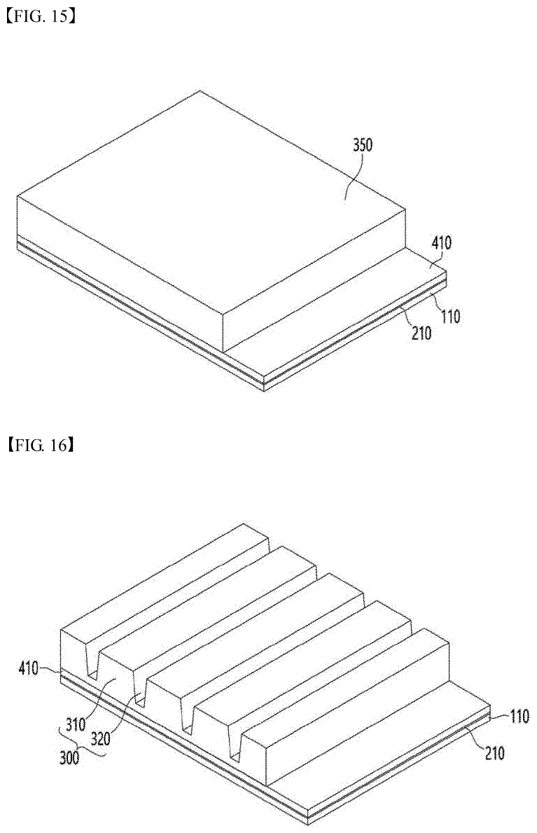

Subsequently, referring to FIG. 15, a resin layer 350 may be formed by coating a resin material on the first electrode 210. In detail, the resin layer 350 may be formed by applying a urethane resin or an acrylic resin on the first electrode 210.

In this case, before disposing the resin layer 350, a buffer layer 410 may be additionally disposed on the first electrode 210. In detail, by disposing the resin layer 350 on the buffer layer 410 after disposing the buffer layer 410 having good adhesion to the resin layer 350 on the first electrode 210, it is possible to improve the adhesion of the resin layer 350.

For example, the buffer layer 410 may include an organic material including a lipophilic group such as —CH—, an alkyl group, etc. Having good adhesion to the electrode and a hydrophilic group such as —NH, —OH, —COOH, etc. Having a good adhesion to the resin layer 410.

The resin layer 350 may be disposed on a partial region of the first substrate 110. That is, the resin layer 350 may be disposed in an area smaller than that of the first substrate 110. Accordingly, a region where the resin layer 350 is not disposed and the first electrode 210 is exposed may be formed on the first substrate 110. In addition, when the buffer layer 410 is disposed on the first electrode 210, a region where the buffer layer 410 is exposed may be formed.

In detail, a size of a third length extending in the first direction of the resin layer 350 may be less than a size of a first length extending in the first direction of the first substrate 110, and a size of a third width extending in the second direction may be less than or equal to a size of a first width extending in the second direction of the first substrate 110.

That is, a length of the resin layer 350 may be smaller than a length of the first substrate 110, and a width of the resin layer 350 may be equal to or smaller than a width of the first substrate 110.

Subsequently, referring to FIG. 16, the resin layer 350 may be patterned to form a plurality of partition wall portions 310 and a plurality of accommodation portions 320 in the resin layer 350. In detail, an engraved portion may be formed in the resin layer 350 to form an engrave-shaped accommodation portion 320 and the emboss-shaped partition wall portion 310 between the engraved portions.

Accordingly, a light conversion part 300 including the partition wall portion 310 and the accommodation portion 320 may be formed on the first substrate 110.

In addition, the buffer layer 410 exposed on the first electrode 210 may be removed to expose the first electrode 210 in a region where the first substrate 110 protrudes.

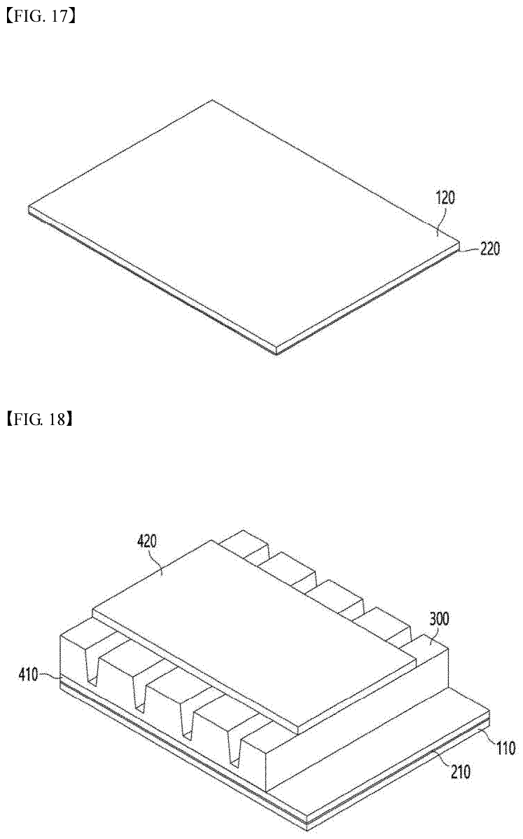

Subsequently, referring to FIG. 17, a second electrode and an electrode material for forming a second substrate 120 and are prepared. Then, the second electrode may be formed by coating or depositing the electrode material on one surface of the second substrate. In detail, the electrode material may be formed on the entire surface of the second substrate 120. Accordingly, the second electrode 220 formed as a surface electrode may be formed on the second substrate 120.

A size of the second substrate 120 may be smaller than that of the first substrate 110. In addition, the size of the second substrate 120 may be smaller than that of the resin layer 350.

In detail, a size of a second length extending in a first direction of the second substrate 120 may be greater than the third length extending in the first direction of the resin layer 350, and a size of a second width extending in a second direction of the second substrate 120 may be smaller than the size of the third width extending in the second direction of the resin layer 350.

Subsequently, referring to FIG. 18, an adhesive layer 420 may be formed by coating an adhesive material on the second electrode 220. In detail, a light-transmitting adhesive layer capable of transmitting light may be formed on the second electrode 220. For example, the adhesive layer 420 may include an optical transparent adhesive layer OCA.

The adhesive layer 420 may be disposed on a partial region of the light conversion part 300. That is, the adhesive layer 420 may be disposed in an area smaller than that of the light conversion part 300. Accordingly, a region where the adhesive layer 410 is not disposed and the light conversion part 300 is exposed may be formed on the light conversion part 300.

In detail, a size of a fourth length extending in a first direction of the adhesive layer 420 may be greater than a size of a third length extending in a first direction of the light conversion part 300, and a size of a fourth width extending in a second direction of the adhesive layer 420 may be smaller than a size of a third width extending in a second direction of the light conversion part 300.

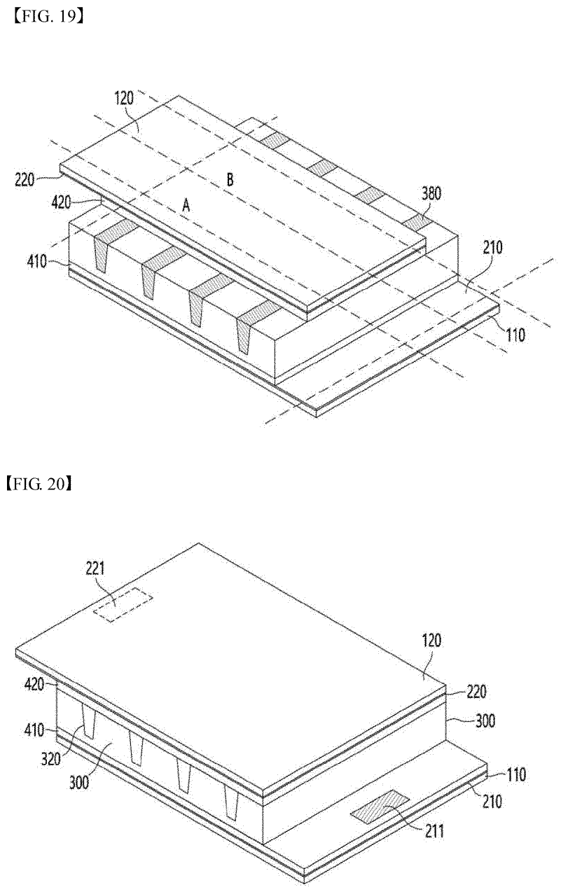

Subsequently, referring to FIG. 19, the first substrate 110 and the second substrate 120 may be adhered. In detail, the second substrate 120 may be disposed on the light conversion part 300, and the second substrate 120 and the light conversion part 300 may be adhered through the adhesive layer 420 disposed under the second substrate 120.

Accordingly, the first substrate 110, the light conversion part 300, and the second substrate 120 may be sequentially stacked in the thickness direction of the first substrate 110, the light conversion part 300, and the second substrate 120.

In this case, since the second substrate 120 is disposed in a size smaller than the size of the resin layer 350, a plurality of partition wall portions 310 and accommodation portions 320 may be exposed in a region where the second substrate 120 is not disposed on the light conversion part 300.

In detail, since the size of the second width extending in the second direction of the second substrate 120 is smaller than the size of the third width extending in the second direction of the resin layer 350, the plurality of partition walls 310 and the accommodation portion 320 may be exposed in an end region of at least one of one end and the other end facing in a width direction of the resin layer 350.

Subsequently, a light conversion material 380 may be injected between the partition wall portions 310, that is, the accommodation portions 320. In detail, a light conversion material in which light absorbing particles such as carbon black are dispersed in an electrolyte solvent including a paraffinic solvent and the like may be injected between the partition wall portions, that is, the accommodation portions 320.

For example, after disposing a dam extending in a longitudinal direction of the light conversion part 300 on the accommodation portion and the partition wall portion of the light conversion part 300 on which the second substrate 120 is not disposed, the electrolyte solvent may be injected into the accommodation portion 320 by a capillary injection method between the dam and a side surface of the light conversion part 300.

Subsequently, one optical path control member may be manufactured by cutting the light conversion part 300. In detail, the light conversion part 300 may be cut in a longitudinal direction of the light conversion part 300. That is, the light conversion part 300, the buffer layer 410 under the light conversion part 300, the first electrode 210, and the first substrate 110 may be cut along the dotted line shown in FIG. 19. A plurality of optical path control members A and B may be formed by the cutting process, and FIG. 20 is a view showing one of the plurality of optical path control members.

In detail, the light conversion part 300 may be cut so that side surfaces of the first substrate 110, the second substrate 120, and the light conversion part 300 in the width direction may be disposed on the same plane.

Accordingly, both ends of the second substrate 120, the second electrode 220, or the adhesive layer 420 in the second direction and both ends of the light conversion part 300 in the second direction may be disposed on the same plane.

That is, the both ends of the adhesive layer 420 in the second direction and the both ends of the light conversion part 300 in the second direction may be connected to each other.

Alternatively, the both ends of the second substrate 120, the second electrode 220, or the adhesive layer 420 in the second direction may be disposed more outside than the both ends of the light conversion part 300 in the second direction according to an error during the process.

Subsequently, the buffer layer 410 disposed on the first substrate 110 and/or the adhesive layer 420 disposed under the second substrate 120 may be partially removed to form a connection portion in which the electrode is exposed. In detail, when the buffer layer 410 is disposed on the first electrode where the light conversion part 300 is not disposed on an upper surface of the first substrate 110, a first connection portion 211 may be formed on the first substrate 110 by removing a part of the first buffer layer 410 to expose the first electrode 210 or by not disposing the buffer layer 410 on the first electrode on which the light conversion unit 300 is not disposed from the beginning. In addition, when the adhesive layer 420 is disposed on the second electrode where the light conversion part 300 is not disposed on a lower surface of the second substrate 120, a second connection portion 221 may be formed under the second substrate 120 by removing a part of the adhesive layer 420 or by not disposing the adhesive layer on the second electrode on which the light conversion part 300 is not disposed during the adhesive process.

A printed circuit board or a flexible printed circuit board may be connected to the connection portions through an anisotropic conductive film (ACF) or the like, and the printed circuit board may be connected to an external power source to apply a voltage to the optical path control member.

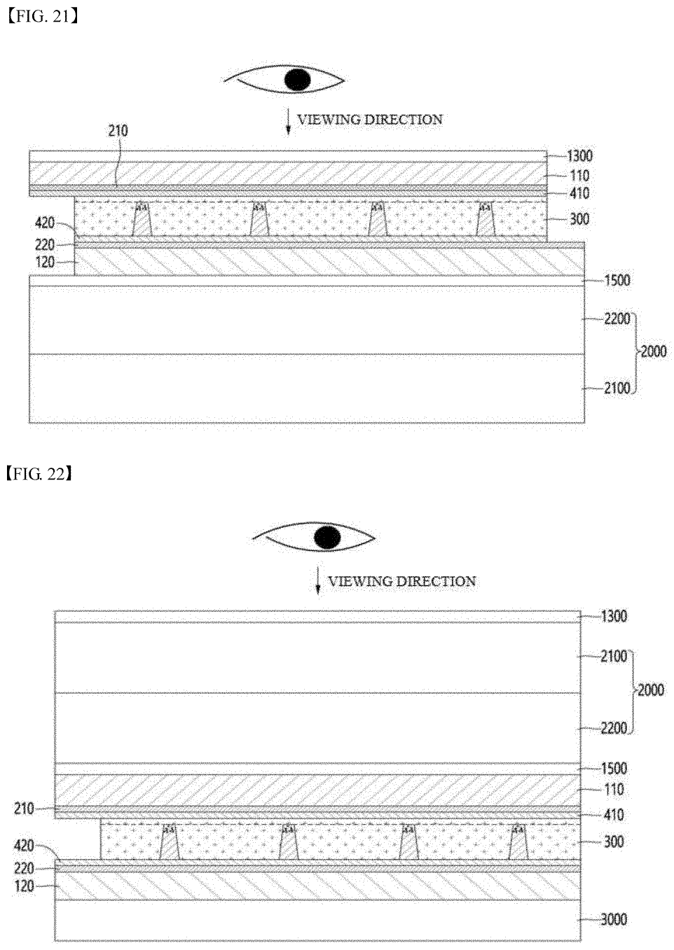

Hereinafter, referring to FIGS. 21 to 25, a display device to which an optical path control member according to an embodiment is applied will be described.

Referring to FIGS. 21 and 22, an optical path control member 1000 according to an embodiment may be disposed on or under a display panel 2000.

The display panel 2000 and the optical path control member 1000 may be disposed to be adhered to each other. For example, the display panel 2000 and the optical path control member 1000 may be adhered to each other via an adhesive layer 1500. The adhesive layer 1500 may be transparent. For example, the adhesive layer 1500 may include an adhesive or an adhesive layer including an optical transparent adhesive material.

The adhesive layer 1500 may include a release film. In detail, when adhering the optical path control member and the display panel, the optical path control member and the display panel may be adhered after the release film is removed.

Meanwhile, referring to FIGS. 21 and 22, one end or one end and the other end of the optical path control member may protrude, and the light conversion part may not be disposed at the protruding portion. The protrusion region is an electrode connection portion in which the first electrode 210 and the second electrode 220 are exposed, and may connect an external printed circuit board and the optical path control member through the electrode connection portion.

The display panel 2000 may include a first′ substrate 2100 and a second′ substrate 2200. When the display panel 2000 is a liquid crystal display panel, the optical path control member may be formed under the liquid crystal panel. That is, when a surface viewed by the user in the liquid crystal panel is defined as an upper portion of the liquid crystal panel, the optical path control member may be disposed under the liquid crystal panel. The display panel 2000 may be formed in a structure in which the first′ substrate 2100 including a thin film transistor (TFT) and a pixel electrode and the second′ substrate 2200 including color filter layers are bonded to each other with a liquid crystal layer interposed therebetween.

In addition, the display panel 2000 may be a liquid crystal display panel of a color filter on transistor (COT) structure in which a thin film transistor, a color filter, and a black electrolyte are formed at the first′ substrate 2100 and the second′ substrate 2200 is bonded to the first′ substrate 2100 with the liquid crystal layer interposed therebetween. That is, a thin film transistor may be formed on the first′ substrate 2100, a protective film may be formed on the thin film transistor, and a color filter layer may be formed on the protective film. In addition, a pixel electrode in contact with the thin film transistor may be formed on the first′ substrate 2100. At this point, in order to improve an aperture ratio and simplify a masking process, the black electrolyte may be omitted, and a common electrode may be formed to function as the black electrolyte.

In addition, when the display panel 2000 is the liquid crystal display panel, the display device may further include a backlight unit 3000 providing light from a rear surface of the display panel 2000.

That is, as shown in FIG. 21, the optical path control member may be disposed under the liquid crystal panel and on the backlight unit 3000, and the optical path control member may be disposed between the backlight unit 3000 and the display panel 2000.

Alternatively, as shown in FIG. 22, when the display panel 2000 is an organic light emitting diode panel, the optical path control member may be formed on the organic light emitting diode panel. That is, when the surface viewed by the user in the organic light emitting diode panel is defined as an upper portion of the organic light emitting diode panel, the optical path control member may be disposed on the organic light emitting diode panel. The display panel 2000 may include a self-luminous element that does not require a separate light source. In the display panel 2000, a thin film transistor may be formed on the first′ substrate 2100, and an organic light emitting element in contact with the thin film transistor may be formed. The organic light emitting element may include an anode, a cathode, and an organic light emitting layer formed between the anode and the cathode. In addition, the second′ substrate 2200 configured to function as an encapsulation substrate for encapsulation may be further included on the organic light emitting element.

That is, light emitted from the display panel 2000 or the backlight unit 3000 may move from the second substrate 120 toward the first substrate 110 of the optical path control member.

In addition, although not shown in drawings, a polarizing plate may be further disposed between the optical path control member 1000 and the display panel 2000. The polarizing plate may be a linear polarizing plate or an external light reflection preventive polarizing plate. For example, when the display panel 2000 is a liquid crystal display panel, the polarizing plate may be the linear polarizing plate. Further, when the display panel 2000 is the organic light emitting diode panel, the polarizing plate may be the external light reflection preventing polarizing plate.

In addition, an additional functional layer 1300 such as an anti-reflection layer, an anti-glare, or the like may be further disposed on the optical path control member 1000. In detail, the functional layer 1300 may be adhered to one surface of the first substrate 110 of the optical path control member. Although not shown in drawings, the functional layer 1300 may be adhered to the first substrate 110 of the optical path control member via an adhesive layer. In addition, a release film for protecting the functional layer may be further disposed on the functional layer 1300.

Further, a touch panel may be further disposed between the display panel and the optical path control member.

It is shown in the drawings that the optical path control member is disposed at an upper portion of the display panel, but the embodiment is not limited thereto, and the optical path control member may be disposed at various positions such as a position in which light is adjustable, that is, a lower portion of the display panel, or between a second substrate and a first substrate of the display panel, or the like.

In addition, it is shown in the drawings that the light conversion part of the optical path control member according to the embodiment is in a direction parallel or perpendicular to an outer surface of the second substrate, but the light conversion part is formed to be inclined at a predetermined angle from the outer surface of the second substrate. Through this, a moire phenomenon occurring between the display panel and the optical path control member may be reduced.

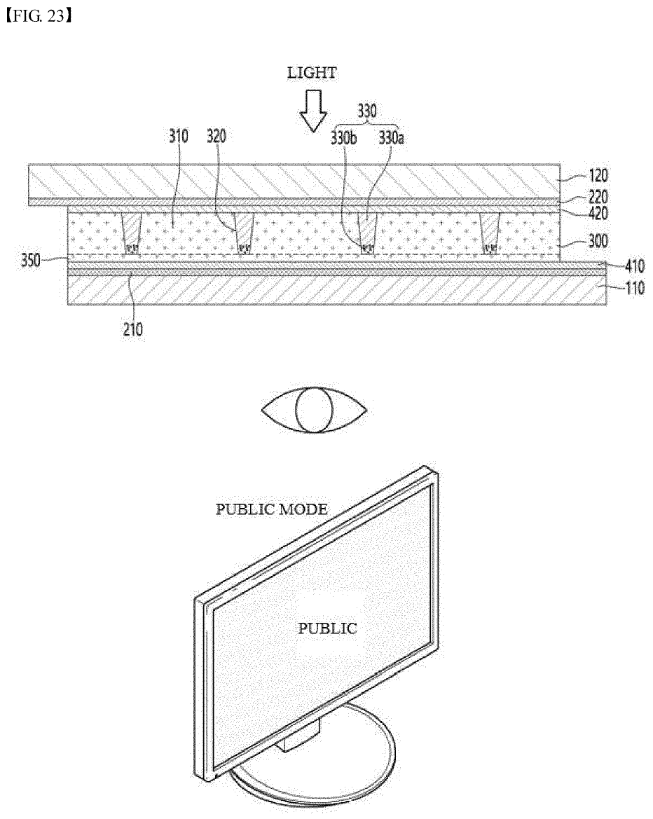

Referring to FIGS. 23 to 25, an optical path control member according to an embodiment may be applied to various display devices.

Referring to FIGS. 23 to 25, the optical path control member according to the embodiment may be applied to a display device that displays a display.

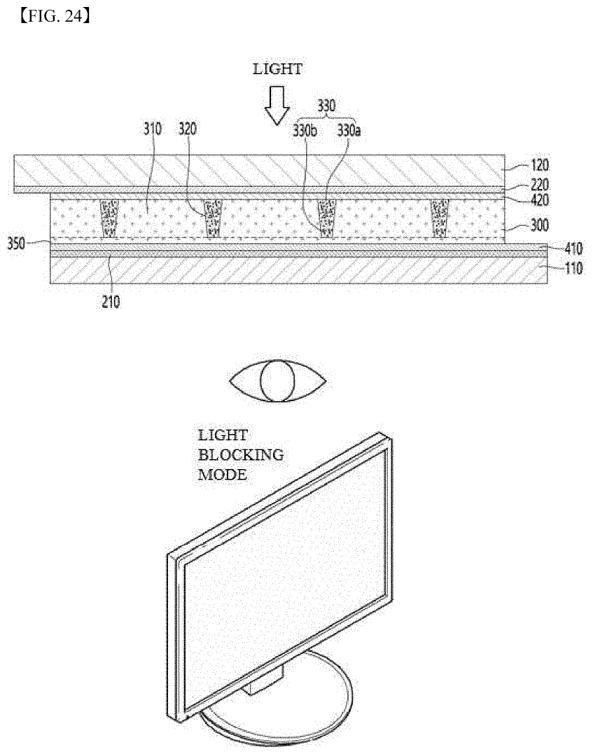

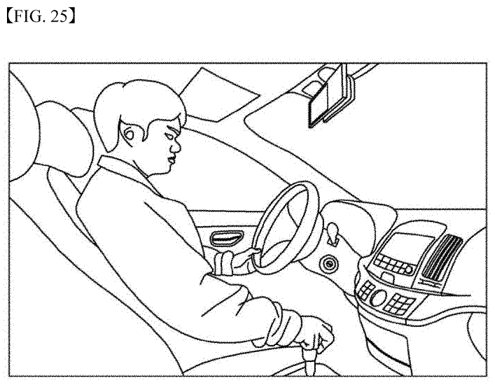

For example, when power is applied to the optical path control member as shown in FIG. 23, the accommodation portion functions as the light transmitting part, so that the display device may be driven in the public mode, and when power is not applied to the optical path control member as shown in FIG. 24, the accommodation portion functions as the light blocking part, so that the display device may be driven in the light blocking mode.

Accordingly, a user may easily drive the display device in a privacy mode or a normal mode according to application of power.

Light emitted from the backlight unit or the self-luminous element may move from the first substrate toward the second substrate. Alternatively, the light emitted from the backlight unit or the self-luminous element may also move from the second substrate toward the first substrate.

In addition, referring to FIG. 25, the display device to which the optical path control member according to the embodiment is applied may also be applied inside a vehicle.

For example, the display device including the optical path control member according to the embodiment may display a video confirming information of the vehicle and a movement route of the vehicle. The display device may be disposed between a driver seat and a passenger seat of the vehicle.

In addition, the optical path control member according to the embodiment may be applied to a dashboard that displays a speed, an engine, an alarm signal, and the like of the vehicle.

Further, the optical path control member according to the embodiment may be applied to a front glass (FG) of the vehicle or right and left window glasses.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically shown in the embodiments may be modified and implemented. In addition, it should be construed that differences related to such a variation and such an application are included in the scope of the present invention defined in the following claims.

1-10. (canceled)

11. An optical path control member comprising:
a first substrate;
a first electrode disposed on the first substrate;
a light conversion part disposed on the first electrode;
a second substrate disposed on the first substrate;
a second electrode disposed under the second substrate; and
an adhesive layer disposed between the light conversion part and the second electrode,
wherein the light conversion part includes a partition wall portion and an accommodation portion alternately disposed,
the accommodation portion has a light transmittance that changes according to application of a voltage,
an upper surface of the partition wall portion is in contact with the adhesive layer,
the light conversion part is formed of a photocurable resin,
the photocurable resin includes an oligomer, a monomer, a photopolymerization initiator, and an additive,
the additive includes an antistatic agent, and
when a weight of the photocurable resin is 100 wt %, the additive is included in an amount of 2.0 wt % to 3.0 wt %.

12. The optical path control member of claim 11, wherein the antistatic agent includes at least one of a nonionic surfactant, a cationic surfactant, an anionic surfactant, and an amphoteric surfactant.

13. The optical path control member of claim 12, wherein the nonionic surfactant includes an amine-based surfactant and a glycerin-based surfactant,
the cationic surfactant includes a quaternary ammonium salt,
the anionic surfactant includes sulfonate and phosphate, and
the amphoteric surfactant includes betaine.

14. The optical path control member of claim 11, wherein the additive further includes a non-reactive release additive.

15. The optical path control member of claim 14, wherein the non-reactive release additive is included in an amount of 0.3 wt % or less.

16. The optical path control member of claim 14, wherein the non-reactive release additive is included in an amount of 0.1 wt % to 0.3 wt %.

17. The optical path control member of claim 14, wherein the non-reactive release additive includes a material in which a functional group is bonded to polydimethylsiloxane.

18. The optical path control member of claim 16, wherein the functional group includes an alkyl group, an aryl group, an allyl group, an alkenyl group, an amido group, an amino group, a fluoroalkyl group, a halide group, an epoxy group, a carboxy group, a hydroxyl group or an alkoxy group, and methylhydrogen.

19. The optical path control member of claim 11, wherein haze of the light conversion part is 9% or less.

20. The optical path control member of claim 11, wherein a lateral transmittance of the light conversion part is 30% or more.

21. The optical path control member of claim 11, wherein the photo-curable resin includes urethane acrylate, acrylate monomers, isobornyl acrylate, additives, photoinitiators, and acryloylmorpholine.

22. The optical path control member of claim 14, wherein the antistatic agent and the non-reactive release additive are included in an amount of 2.4 wt % to 2.8 wt %.

23. The optical path control member of claim 11, wherein the accommodation portion accommodates light conversion particles and a dispersion liquid,
the light conversion particles include carbon black, and
the dispersion liquid includes a surfactant reacting with the additive.

24. The optical path control member of claim 23, wherein the surfactant includes at least one of a nonionic surfactant, a cationic surfactant, and an anionic surfactant, and an amphoteric surfactant.

25. The optical path control member of claim 23, wherein the light conversion particles move in a direction of the first electrode or the second electrode by an applied voltage.

26. A display device comprising:
a display panel; and
the optical path control member according to claim 11 disposed on the display panel.
